(19) United States
(12) Patent Application Publication
(10) Pub. No.: US 2009/0117727 A1
(43) Pub. Date: May 7, 2009

(54) METHOD OF FORMING A FLASH MEMORY

(75) Inventor: Chih-Hsiung HUNG, Taipei (TW)

Correspondence Address: INGRASSIA FISHER & LORENZ, P.C., 7010 E. COCHISE ROAD, SCOTTSDALE, AZ, 85253, US

(73) Assignee: NANYA TECHNOLOGY CORP., Taoyuan (TW)

(21) Appl. No.: 12/035,553

(22) Filed: Feb. 22, 2008

(30) Foreign Application Priority Data
Nov. 5, 2007 (TW) 096141672

(51) Int. Cl. H01L 21/283

(52) U.S. Cl. 438/593; 257/E21.422

(57) ABSTRACT

A method of forming a flash memory is provided. The method includes the steps of providing a substrate; forming a plurality of floating gates on the substrate; forming a first conformal dielectric layer to cover the substrate and the plurality of floating gates; forming a second conformal dielectric layer to cover the first conformal dielectric layer; partially removing the second conformal dielectric layer to partially expose the first conformal dielectric layer; forming a conformal precursor layer to cover the second conformal dielectric layer and the exposed portion of the-first conformal dielectric layer; oxidizing the conformal precursor layer to form a control gate dielectric layer between the plurality of floating gates; and forming a control gate on the control gate dielectric layer.

### CROSS REFERENCE TO RELATED APPLICATIONS

This application claims the right of priority based on Taiwan Patent Application No. 96141672 entitled “METHOD OF FORMING FLASH MEMORY”, filed on Nov. 5, 2007, which is incorporated herein by reference and assigned to the assignee herein.

### FIELD OF THE INVENTION

The present invention relates to a semiconductor structure and a fabricating method of the same, and more particularly, relates to a semiconductor structure of a flash memory and a fabricating method of the same.

### BACKGROUND OF THE INVENTION

Flash memories are non-volatile memory devices that can retain the written data even after the power supply is turned off. Flash memories have been commonly used for various electronic apparatus, for example, digital cameras, digital video cameras, mobile phones and notebooks, etc. Generally, the structure of a flash memory may include a floating gate for storing charges and a control gate for accessing data. The control gate electrically connects to words lines while the floating gate is isolated without linking to any wires. When data is written into the flash memory, electrons are trapped in the floating gate and thus the data can be stored for a long time. When removing the data is requested, an appropriated voltage can be applied to the control gate to drive the electrons away.

Flash memories have developed into diverse structures. FIG. 1 illustrates a cross-sectional view of an optimum flash memory. As shown in FIG. 1, a flash memory 10 is formed on a substrate 11. The flash memory 10 includes a control gate 12 and two floating gates 13 respectively located at two sides of the control gate 12. The floating gate 13 is separated from the control gate 13 by a vertical dielectric layer 14. The vertical dielectric layer 14 is also named as an ONO layered structure, which includes a bottom oxide layer 15, a nitride layer 16 and a top oxide layer 17. The control gates 12 and the floating gates 13 are respectively isolated from the substrate 11 by a control gate oxide 19 and a floating gate oxide 18.

By way of the conventional method, it is difficult to achieve the optimum flash memory 10 as shown in FIG. 1. For example, referring to FIG. 2A, for forming the ONO layered structure (i.e. the vertical dielectric layer 14), the oxide layer 15 and the nitride layer 16 are sequentially deposited on the surface of the floating gates 13, following by a wet oxidation to form the top oxide layer 17 on the surface of the nitride layer 16. Since the nitride 17 resists the oxidation, in order to get sufficient oxides on the surface, the wet oxidation should be conducted for a much longer time under a significantly high temperature, and these conditions are unfavorable to the manufacturing cost. In addition, as shown in FIG. 2B, after the vertical dielectric layer 14 is formed, a dry etching is conducted to expose substrate 11. Then, the substrate 11 is placed into a furnace to oxidize the exposed portion of the substrate 11. The resultant structure is shown as FIG. 2C, wherein the control gate oxide 19′ is formed as a beak being thinner on two ends and thicker in the center. To deposit the control gate 12 on the control gate oxide 19′ is unfavorable because it tends to lead to current leakages at the thinner two ends.

Therefore, there is a need to provide an inventive method to address the conventional problems and build a desired flash memory.

### SUMMARY OF THE INVENTION

In order to obviate the previously mentioned drawbacks, one aspect of the present invention is to provide a method of forming a flash memory. The method includes the steps of providing a substrate; forming a plurality of floating gates on the substrate; forming a first conformal dielectric layer to cover the substrate and the plurality of floating gates; forming a second conformal dielectric layer to cover the first conformal dielectric layer; partially removing the second conformal dielectric layer to partially expose the first conformal dielectric layer; forming a conformal precursor layer to cover the second conformal dielectric layer and the exposed portion of the first conformal dielectric layer; oxidizing the conformal precursor layer to form a control gate dielectric layer between the plurality of floating gates; and forming a control gate on the control gate dielectric layer.

In one embodiment, the present invention provides amorphous silicon as the material of the conformal precursor layer.

In another embodiment, the present invention provides tetrathylorthosilicate (TEOS) as the material of the conformal precursor layer.

In still another embodiment, the step of oxidizing the conformal precursor layer to form the control gate dielectric layer between the pluralities of floating gates further includes forming a plurality of top dielectric layers over the plurality of floating gates at the same time.

By way of the present invention, the control gate dielectric and the top dielectric layer can be built simultaneously, wherein the top dielectric layer are formed without the need of such a long time and such a significantly high temperature as the conventional method does, and consequently the beak structure of the control gate oxide layer is improved.

### BRIEF DESCRIPTION OF THE DRAWINGS

FIG. 1 illustrates a cross-sectional view of a conventional flash memory.

FIG. 2A to FIG. 2C illustrate respective cross-sectional views for various stages of forming a conventional flash memory.

FIG. 3 to FIG. 9 illustrate respective cross-sectional views for various stages of forming a flash memory in accordance with one embodiment of the present invention.

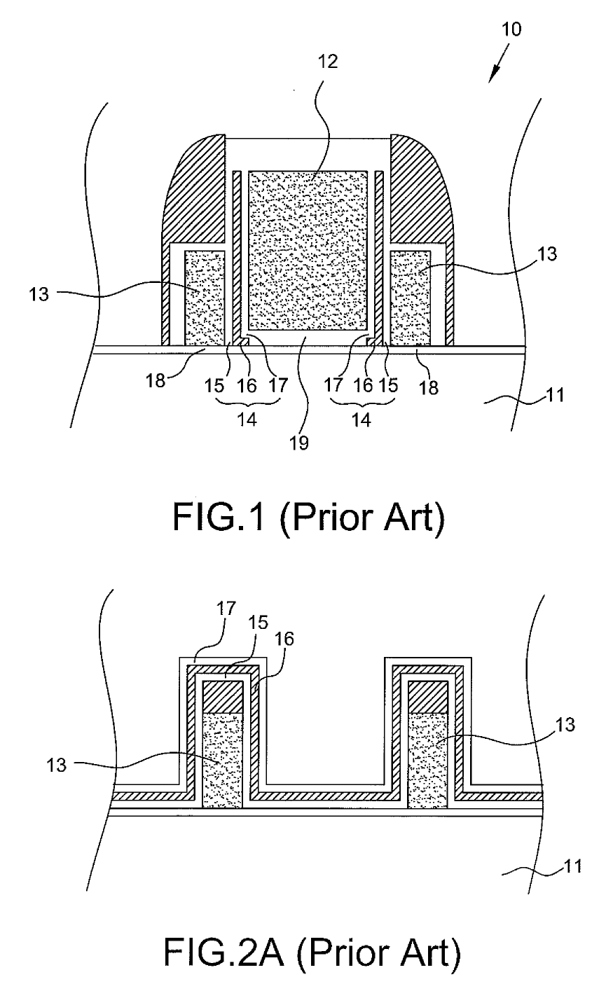

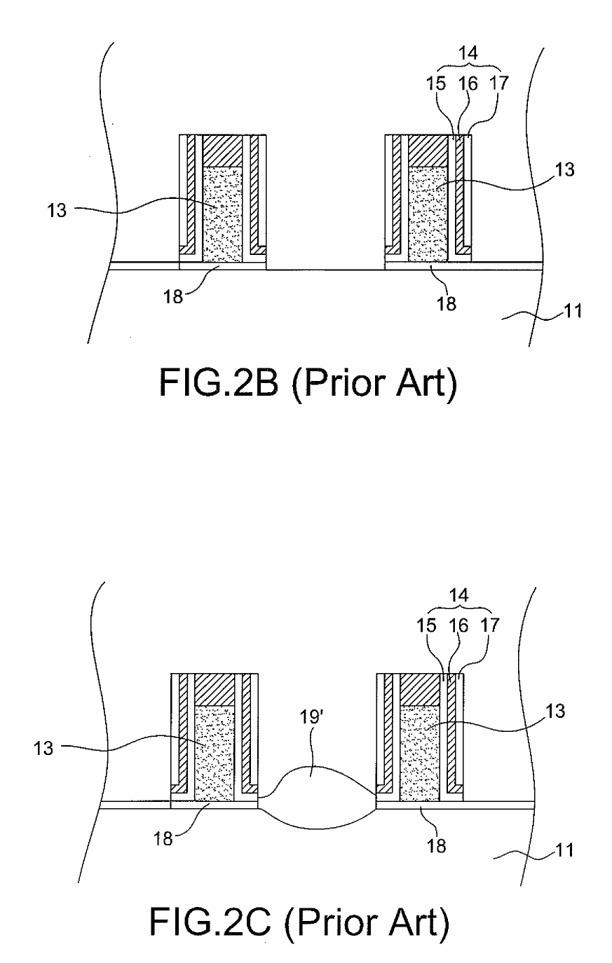

### DETAILED DESCRIPTION OF THE INVENTION

The present invention may best be understood by reference to the following description in conjunction with the accompanying drawings, in which similar reference numbers represent similar elements. Any devices, components, materials, and steps described in the embodiments are only for illustration and not intended to limit the scope of the present invention. It should be noted that the features illustrated in the drawings are not necessarily drawn to scale. Descriptions of well-known components, materials, and process techniques are omitted so as not to unnecessarily obscure the embodiments of the invention.

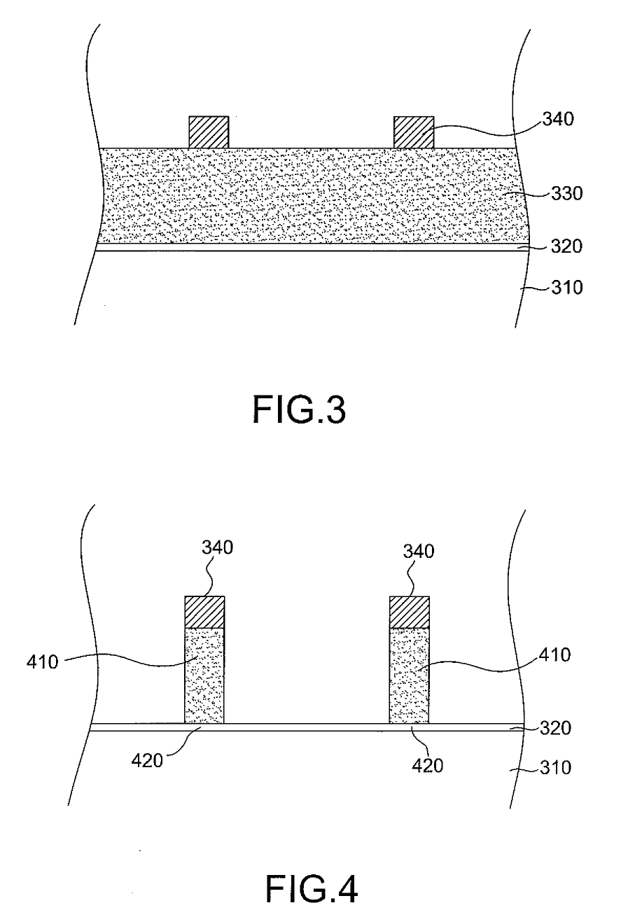

FIG. 3 to FIG. 9 illustrate respective cross-sectional views for various stages of forming a flash memory in accordance with one embodiment of the present invention. As shown in FIG. 3, a substrate 310 is provided and followed by depositing an insulating layer 320, a conductive layer 330 and a patterned sacrificial layer 340 on the substrate 310. The substrate 310 may be any suitable semiconductor substrate, which includes but not limited to a silicon substrate. The insulating layer 320 can be an oxide layer with a thickness from 50 Å to 100 Å by a wet oxidation. The conductive layer 330 is preferably composed of polysilicon with a thickness from 200 Å to 300 Å. The patterned sacrificial layer 340 is provided for defining the floating gates to be made. The patterned sacrificial layer 340 can be nitride or any other suitable materials. It should be appreciated that the conductive layer 330 and the patterned sacrificial layer 340 can be formed by well-known chemical vapor deposition and any appropriate lithography technologies.

Referring to FIG. 3 and FIG. 4, a plurality of floating gates 410 are formed by etching the conductive layer 330 with the patterned sacrificial layer 340 as a mask. The etching step can be performed using chemicals with a higher selectivity to the conductive layer 330 in comparison with the insulating layer 320 and the patterned sacrificial layer 340. Although the embodiment illustrates two floating gates 410 as shown in FIG. 4, it is not intended to limit the numbers of floating gates while more than two of the floating gates are also applied to the present invention. In addition, note that the insulating layer 320 below the floating gate 410 is now referred as a floating gate insulating layer 420.

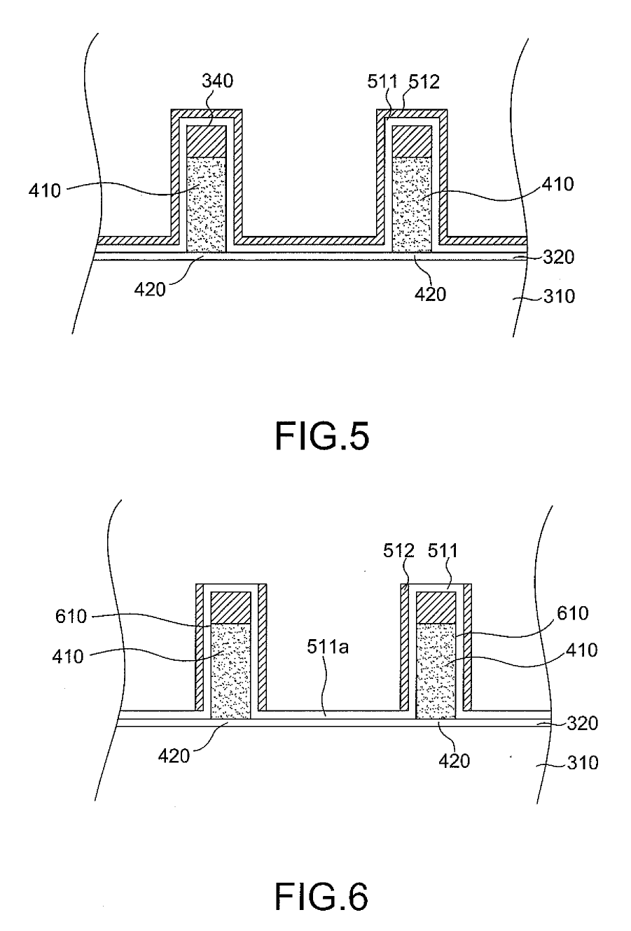

Referring to FIG. 5, after the structure of FIG. 4 is formed, a first conformal dielectric layer 511 and a second conformal dielectric layer 512 are deposited in sequence to cover the insulating layer 320 (i.e. 420), a plurality of floating gates 410 and the patterned sacrificial layer 340 above thereof. Preferably, the first conformal dielectric later 511 is composed of oxide, being either named as a bottom oxide layer 511 due to the position below the second conformal dielectric layer 512. The preferred material of the second conformal dielectric layer 512 is nitride, so that it is either named as a nitride layer 512.

Referring to FIG. 6, after the first conformal dielectric layer 511 and the second conformal dielectric layer 512 are formed, the second conformal dielectric layer 512 is partially removed by a dry etching to expose a portion of the first conformal dielectric layer 511a. The dry etching can be conducted using reactive gas with a higher selectivity to the second conformal dielectric layer 512 in comparison with the first conformal dielectric 511. As being anisotropic during the dry etching, the portion of the second conformal dielectric layer 512 over the side walls 610 of the floating gates 410 are remained. Note that the portion of the second conformal dielectric layer 512 over the top of the patterned sacrificial layer 340 is also removed by the dry etching process.

After the structure of FIG. 6 is formed, an optional step of cleaning the remained second conformal dielectric layer 512 and the exposed first conformal dielectric layer 51i a can be conducted to avoid undesired residue. A conventional plasma dry cleaning apparatus can be used in the optional step.

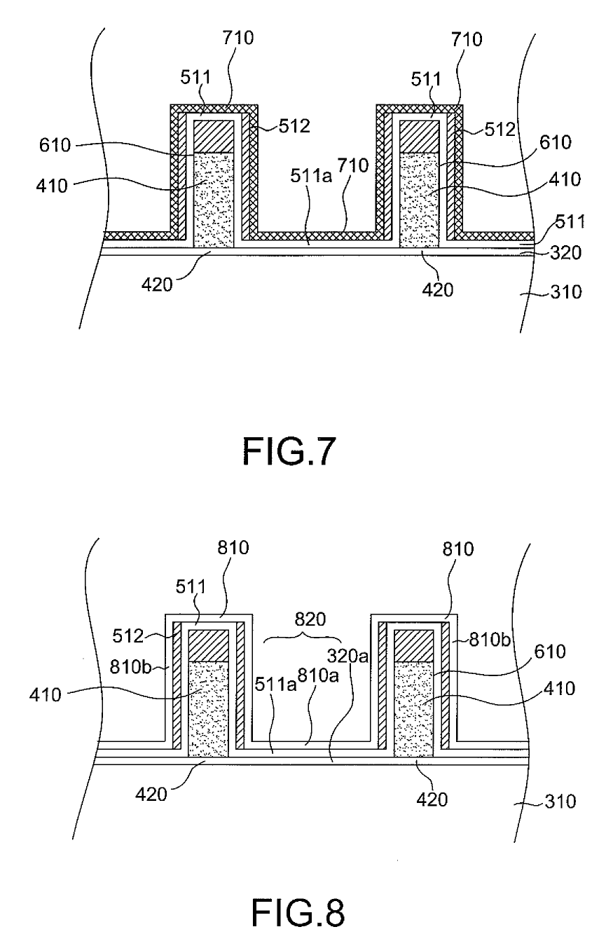

Referring FIG. 7, a low pressure chemical vapor deposition (LPCVD) is conducted to form a conformal precursor layer 710 to cover_the second conformal dielectric layer 512 and the exposed first conformal dielectric layer 511a. The conformal precursor layer 710 may include amorphous silicon, tetraethylorthosilicate (TEOS), or any other suitable materials. Preferably, in the embodiment of amorphous silicon, the thickness of the conformal precursor layer 710 is around 3 nanometer. In the embodiment of tetraethylorthosilicate (TEOS), the thickness of the conformal precursor layer 710 varies depending upon the related location. For example, the thickness of TEOS located on the exposed first conformal dielectric layer 511a is around 10 nanometer while the thickness of those located on the second conformal dielectric layer 512 (i.e. also on the sidewalls 610 of the floating gates 410) is around 7 nanometer.

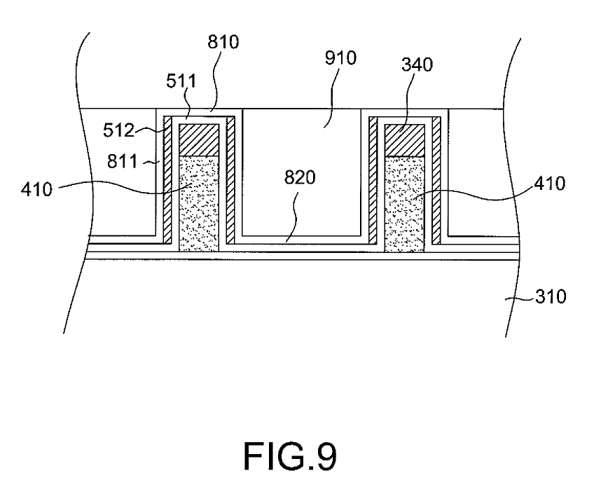

Next, the conformal precursor layer 710 is converted into a conformal oxide layer 810 by way of oxidation, which can be conducted through conventional dry or wet oxidation processes. The resultant structure after the oxidation is shown in FIG.8, wherein note that the stack over the side wall 610 of the floating gates 410 includes a first conformal dielectric layer 511 (i.e. the bottom oxide layer 511), the second conformal dielectric layer 512 (i.e. the nitride layer 512), and the conformal oxides layer 810. The conformal oxide layer 810 over the nitride 512 and the bottom oxide layer 511 of the stack is either named as a top oxide layer 810b. In addition, note that the portions of the first conformal dielectric layer 511a between the plurality of floating gates are also covered by the conformal oxide layer 810 (i.e. 810a). The conformal oxide layer 810a, the underlying first conformal dielectric layer 511 a and the underlying insulating layer 320a are named as a control gate oxide layer 820. In other words, the control gate oxide layer 820 is a stack made by at least three steps as aforementioned. In the embodiment, the preferred thickness of the control gate oxide layer 820 is around 200 Å. FIG. 9 illustrates that after the control gate oxide 820 is formed, a control gate 910 can be deposited thereon using any suitable conductive materials such as polysilicon.

The present invention has been described above with reference to preferred embodiments. However, those skilled in the art will understand that the scope of the present invention need not be limited to the disclosed preferred embodiments. On the contrary, it is intended to cover various modifications and equivalent arrangements within the scope defined in the following appended claims. The scope of the claims should be accorded the broadest interpretation so as to encompass all such modifications and equivalent arrangements.

What is claimed is:

1. A method of forming a flash memory, comprising the steps of:
providing a substrate;
forming a plurality of floating gates on the substrate;
forming a first conformal dielectric layer to cover the substrate and the plurality of floating gates;
forming a second conformal dielectric layer to cover the first conformal dielectric layer;
partially removing the second conformal dielectric layer to partially expose the first conformal dielectric layer;
forming a conformal precursor layer to cover the second conformal dielectric layer and the exposed portion of the first conformal dielectric layer;
oxidizing the conformal precursor layer to form a control gate dielectric layer between the plurality of floating gates; and
forming a control gate on the control gate dielectric layer.

2. The method of forming a flash memory as claimed in claim 1, further comprising forming a floating gate insulating layer on the substrate prior to the step of forming plurality of floating gates on the substrate.

3. The method of forming a flash memory as claimed in claim 1, wherein the step of forming the first conformal dielectric layer comprises:
forming a bottom oxide layer over an insulating layer formed on the substrate.

4. The method of forming a flash memory as claimed in claim 3, wherein the step of forming the second conformal dielectric layer comprises:
forming a nitride layer over the bottom oxide layer.

5. The method of forming a flash memory as claim 1, wherein the conformal precursor layer comprises amorphous silicon.

6. The method as claimed in claim 4, wherein the conformal precursor layer comprises tetrathylorthosilicate (TEOS).

7. The method of forming a flash memory as claim 1, wherein the step of forming the conformal precursor layer over the second conformal dielectric layer and the exposed first conformal dielectric layer is preformed by a low pressure chemical vapor deposition (LPCVD).

8. The method of forming a flash memory as claim 1, wherein the step of oxidizing the conformal precursor layer to form the control gate dielectric layer between the plurality of floating gates comprises:
forming a plurality of top dielectric layers over the plurality of floating gates.

9. The method of forming a flash memory as claim 8, wherein the step of oxidizing the conformal precursor layer to form the control gate dielectric layer between the plurality of floating gates is performed by a dry oxidation.

10. The method of forming a flash memory as claim 8, wherein the step of oxidizing the conformal precursor layer to form the control gate dielectric layer between the plurality of floating gates is performed by a wet oxidation.
